(19) United States
(12) Patent Application Publication
(10) Pub. No.: US 2026/0150597 A1
(43) Pub. Date: May 28, 2026

(54) METHOD OF MANUFACTURING SEMICONDUCTOR DEVICE

(71) Applicant: Renesas Electronics Corporation, Tokyo (JP)

(72) Inventors: Kodai OZAWA, Tokyo (JP); Shinji INOUE, Tokyo (JP)

(21) Appl. No.: 19/320,821

(22) Filed: Sep. 5, 2025

(30) Foreign Application Priority Data
Nov. 25, 2024 (JP) 2024-204930

(51) Int. Cl. H01L 21/225; H01L 21/265; H01L 21/268; H10D 8/01; H10D 12/01

(52) U.S. Cl. CPC H10P 32/171; H10D 8/045; H10D 12/032; H10P 30/204; H10P 30/208; H10P 32/1408; H10P 34/42

(57) ABSTRACT

A method of manufacturing a semiconductor device includes: forming a diffusion source on a lower surface of a semiconductor substrate to diffuse conductive impurities into the semiconductor substrate, and irradiating the lower surface of the semiconductor substrate with laser light through the diffusion source.

### CROSS-REFERENCE TO RELATED APPLICATIONS

The disclosure of Japanese Patent Application No. 2024-204930 filed on Nov. 25, 2024, including the specification, drawings and abstract is incorporated herein by reference in its entirety.

### BACKGROUND

The present disclosure relates to a method of manufacturing a semiconductor device. For example, the present disclosure relates to a method of manufacturing a semiconductor device including an Insulated Gate Bipolar Transistor (IGBT) or a diode.

There are disclosed techniques listed below.
[Patent Document 1] Japanese Unexamined Patent Application Publication No. 2023-173191

Patent Document 1 discloses a technique for reducing the leakage current of a semiconductor device including an IGBT or a diode.

### SUMMARY

For example, there is a semiconductor device having a lower electrode on a lower surface of a semiconductor substrate. In such a semiconductor device, it is important to make contact between the lower electrode and the semiconductor substrate with low resistance to improve the performance of the semiconductor device. That is, in the aforementioned semiconductor device, it is desired to improve the contact between the lower electrode and the semiconductor substrate.

Other problems and novel features will become apparent from the description herein and from the accompanying drawings.

In one embodiment, a method of manufacturing a semiconductor device includes: forming a diffusion source on a lower surface of a semiconductor substrate to diffuse conductive impurities into the semiconductor substrate, and irradiating the lower surface of the semiconductor substrate with laser light through the diffusion source.

According to one embodiment, in a semiconductor device having a lower electrode on the lower surface of the semiconductor substrate, the contact between the lower electrode and the semiconductor substrate can be improved.

### BRIEF DESCRIPTION OF THE DRAWINGS

FIG. 1 is a cross-sectional view showing the configuration of a semiconductor device including an IGBT.

FIG. 2 is a flowchart explaining the basic concept.

FIG. 3 is a flowchart explaining a first embodiment.

FIG. 4 is a diagram showing a manufacturing step of the semiconductor device in the first embodiment.

FIG. 5 is a diagram showing the manufacturing step of the semiconductor device following FIG. 4.

FIG. 6 is a diagram showing the manufacturing step of the semiconductor device following FIG. 5.

FIG. 7 is a diagram showing the manufacturing step of the semiconductor device following FIG. 6.

FIG. 8 is a diagram showing the manufacturing step of the semiconductor device following FIG. 7.

FIG. 9 is a diagram schematically showing the result of observing the lower surface of the semiconductor substrate with a microscope when laser annealing is performed without forming a film.

FIG. 10 is a diagram schematically showing the result of observing the lower surface of the semiconductor substrate with a microscope after removing the film when laser annealing is performed with a film formed.

FIG. 11 is a flowchart explaining a second embodiment.

FIG. 12 is a flowchart explaining a third embodiment.

FIG. 13 is a diagram showing a manufacturing step of the semiconductor device in the third embodiment.

FIG. 14 is a diagram showing the manufacturing step of the semiconductor device following FIG. 13.

FIG. 15 is a circuit diagram configuring an arm.

FIG. 16 is a cross-sectional view showing the configuration of the semiconductor device in a fifth embodiment.

FIG. 17 is a plan view showing the configuration of the semiconductor device in a sixth embodiment.

FIG. 18 is a diagram showing an examined example.

FIG. 19 is a cross-sectional view of the semiconductor device along line A-A of FIG. 17.

FIG. 20 is a cross-sectional view showing the configuration of the semiconductor device in a seventh embodiment.

### DETAILED DESCRIPTION

In all the drawings for explaining the embodiments, the same reference numerals are used for the same members in principle, and repetitive descriptions thereof are omitted. Note that even plan views may be hatched for the sake of clarity.

### Configuration of Semiconductor Device Including IGBT

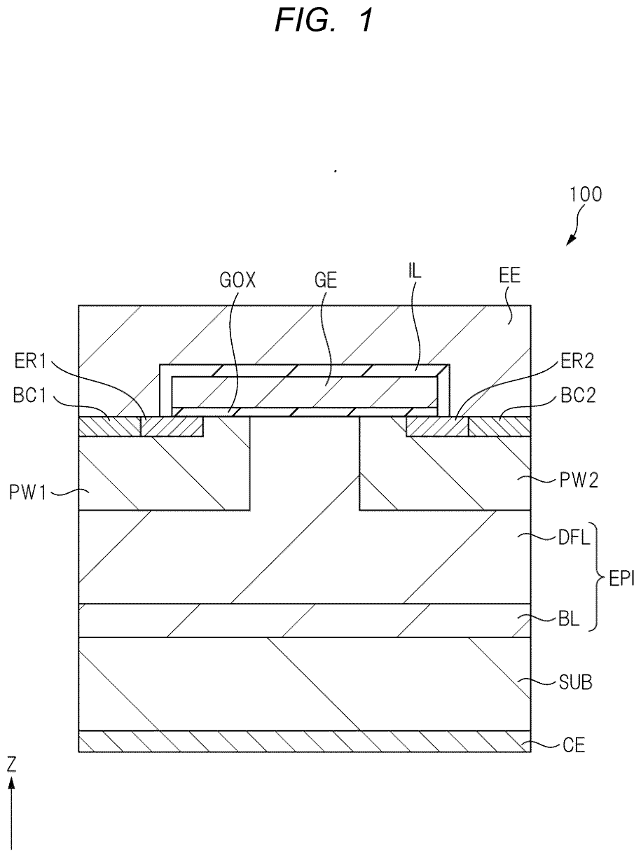

FIG. 1 is a cross-sectional view showing a configuration of a semiconductor device 100 including an IGBT.

In FIG. 1, the semiconductor device 100 includes a semiconductor substrate SUB, a buffer layer BL, a drift layer DFL, a p-type well PW1, a p-type well PW2, a body contact region BC1, a body contact region BC2, a gate insulating film GOX, a gate electrode GE, an interlayer insulating film IL, a collector electrode CE, an emitter region ER1, an emitter region ER2, and an emitter electrode EE.

The semiconductor substrate SUB is a p-type silicon substrate. That is, for example, boron, which is a p-type impurity, is introduced into the semiconductor substrate SUB. An epitaxial layer EPI is formed on the upper surface of the semiconductor substrate SUB. The epitaxial layer EPI includes the buffer layer BL and the drift layer DFL. Since the epitaxial layer EPI is an n-type semiconductor layer, a pn junction is formed by the semiconductor substrate SUB and the epitaxial layer EPI. A collector electrode CE is formed on the lower surface of the semiconductor substrate SUB. The collector electrode CE is a lower electrode.

In the epitaxial layer EPI, the p-type well PW1 and the p-type well PW2 are formed. In the p-type well PW1, the emitter region ER1 and the body contact region BC1 are formed. The emitter region ER1 is an n-type semiconductor region. On the other hand, the body contact region BC1 is a p-type semiconductor region. The emitter region ER1 and the body contact region BC1 are in contact with each other. In the p-type well PW2, the emitter region ER2 and the body contact region BC2 are formed. The emitter region ER2 is an n-type semiconductor region. On the other hand, the body contact region BC2 is a p-type semiconductor region. The emitter region ER2 and the body contact region BC2 are in contact with each other.

The gate insulating film GOX is formed on the epitaxial layer EPI. The gate electrode GE is formed on the gate insulating film GOX. The interlayer insulating film IL is formed on the epitaxial layer EPI so as to cover the gate electrode GE. The emitter electrode EE is formed on the interlayer insulating film IL.

The emitter electrode EE is electrically connected to the emitter region ER1 and the body contact region BC1. Therefore, the emitter region ER1 and the body contact region BC1 are electrically connected via the emitter electrode EE.

Additionally, the emitter electrode EE is electrically connected to the emitter region ER2 and the body contact region BC2. Therefore, the emitter region ER2 and the body contact region BC2 are electrically connected via the emitter electrode EE.

When 0 V is applied to the emitter electrode EE and a positive voltage is applied to the collector electrode CE, and a gate voltage equal to or greater than the threshold voltage is applied to the gate electrode GE, the IGBT turns on. Specifically, when a gate voltage equal to or greater than the threshold voltage is applied to the gate electrode GE, a channel is formed on a surface of the p-type well PW1, and the emitter region ER1 and the drift layer DFL are electrically connected to each other. Similarly, a channel is formed on a surface of the p-type well PW2, and the emitter region ER2 and the drift layer DFL are electrically connected to each other.

Since the emitter electrode EE, the emitter region ER1, the emitter region ER2, and the drift layer DFL are electrically connected to each other, when 0 V is applied to the emitter electrode EE, 0 V is also applied to the drift layer DFL. On the other hand, since the semiconductor substrate SUB is electrically connected to the collector electrode CE, when a positive voltage is applied to the collector electrode CE, a positive voltage is also applied to the semiconductor substrate SUB. Therefore, a forward bias is applied to the pn junction formed by the semiconductor substrate SUB and the epitaxial layer EPI.

As a result, holes are injected from the collector electrode CE into the epitaxial layer EPI via the semiconductor substrate SUB. Then, electrons are injected into the epitaxial layer EPI from the emitter electrode EE through the emitter region ER1 and the emitter region ER2, the channel, and the drift layer DFL, as if attracted by the injected holes. This causes a conductivity modulation phenomenon, reducing the resistance in the epitaxial layer EPI. In other words, the conductivity modulation phenomenon allows the on-resistance of the IGBT to be reduced.

Subsequently, when a gate voltage smaller than the threshold voltage is applied to the gate electrode GE, the IGBT turns off. Specifically, when the discharge of holes injected into the epitaxial layer EPI to the emitter electrode EE and the discharge of electrons injected into the epitaxial layer EPI to the collector electrode CE are completed, the IGBT turns off. That is, the tail current due to the discharge of holes and electrons flows, and after the tail current ceases to flow, the IGBT turns off.

### Room for Improvement

The problem that the technical idea of this disclosure seeks to solve is to improve the contact between the lower electrode and the lower surface of the semiconductor substrate. An example of room for improvement is described below. In particular, the room for improvement described here is a specific issue focusing on a semiconductor device including an IGBT. Therefore, the problem that the technical idea of this disclosure seeks to solve is not limited to the specific room for improvement described here. The problem that the technical idea of this disclosure seeks to solve is to improve the contact between the lower electrode and the lower surface of the semiconductor substrate in a semiconductor device having a lower electrode on the lower surface of the semiconductor substrate.

The room for improvement in a semiconductor device including an IGBT is described below.

To reduce the on-voltage of a semiconductor device including an IGBT, it is necessary to secure sufficient contact between the lower surface of the semiconductor substrate SUB and the collector electrode CE. For this purpose, for example, p-type impurities are introduced into the semiconductor substrate SUB from the lower surface of the semiconductor substrate SUB by ion implantation method. Subsequently, laser annealing is performed to irradiate the lower surface of the semiconductor substrate SUB with laser light. This activates the p-type impurities introduced into the semiconductor substrate SUB. Then, the collector electrode CE made of a conductive film is formed on the lower surface of the semiconductor substrate SUB. This forms an ohmic contact between the lower surface of the semiconductor substrate SUB and the collector electrode CE. As a result, sufficient contact between the lower surface of the semiconductor substrate SUB and the collector electrode CE can be secured.

However, in the above step, the impurity concentration of the p-type impurities introduced near the lower surface of the semiconductor substrate SUB becomes lower than the peak value. In other words, the peak value of the impurity concentration of the p-type impurities introduced into the semiconductor substrate SUB is away from the lower surface of the semiconductor substrate SUB. Therefore, from the perspective of securing sufficient contact between the lower surface of the semiconductor substrate SUB and the collector electrode CE, the inventor has newly found that there is a need for improvement. In particular, in IGBTs where the impurity concentration of the p-type impurities introduced from the lower surface of the semiconductor substrate SUB is low, the decrease in contact between the lower surface of the semiconductor substrate SUB and the collector electrode CE becomes apparent.

For example, in IGBTs where high-speed switching operations are performed, the number of switching cycles increases. Therefore, in IGBTs for high-speed switching applications, switching losses during switching increase.

Therefore, in IGBTs for high-speed switching applications, it is important to reduce switching losses. To reduce switching losses, it is effective to reduce the tail current flowing during turn-off. This is because reducing the tail current means that the time during which the tail current flows can be shortened. In other words, if the time during which the tail current flows can be shortened, the turn-off period during which switching losses occur can be shortened. Therefore, in IGBTs for high-speed switching applications, it is desirable to reduce the tail current to reduce switching losses.

The tail current is due to the discharge of holes and electrons injected into the epitaxial layer EPI. Therefore, to reduce the tail current, it is effective to reduce the holes injected into the epitaxial layer EPI during on-state. Reducing the holes injected into the epitaxial layer EPI can be achieved by reducing the impurity concentration of the p-type impurities introduced into the semiconductor substrate SUB, which is the source of the holes. Therefore, in IGBTs for high-speed switching applications, the impurity concentration of the p-type impurities introduced from the lower surface of the semiconductor substrate SUB is reduced. However, in this case, as mentioned above, the decrease in contact between the lower surface of the semiconductor substrate SUB and the collector electrode CE becomes apparent. From the above, it is desired to improve the contact between the lower surface of the semiconductor substrate SUB and the collector electrode CE.

### Basic Idea

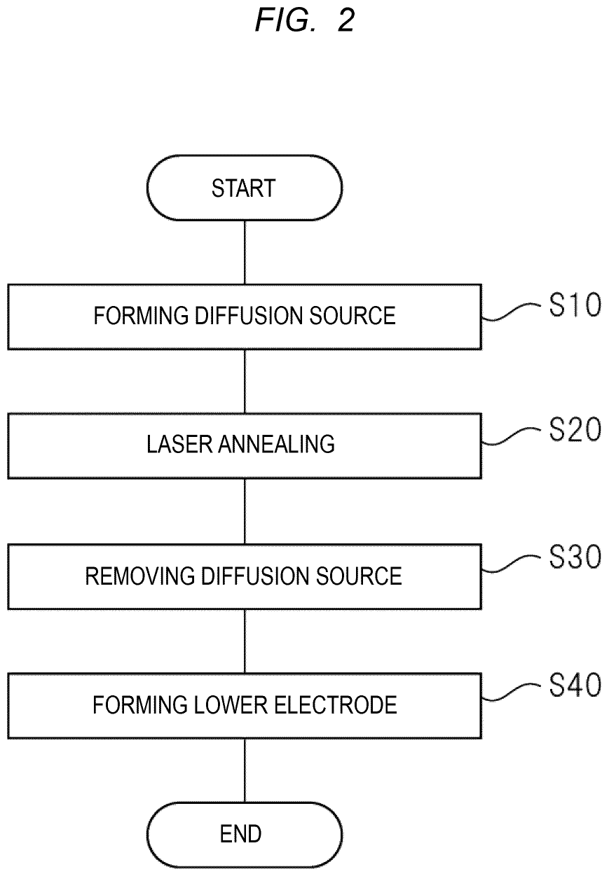

FIG. 2 is a flowchart explaining the basic idea.

In FIG. 2, the basic idea includes a step of forming a diffusion source on the lower surface of the semiconductor substrate SUB to diffuse conductive impurities into the semiconductor substrate SUB (S10), and a step of irradiating the lower surface of the semiconductor substrate SUB with laser light through the diffusion source (S20). The basic idea includes a step of removing the diffusion source (S30) and a step of forming a lower electrode on the lower surface of the semiconductor substrate SUB (S40). However, the step of removing the diffusion source may not be necessary.

That is, the step of removing the diffusion source is carried out as needed. The step of irradiating laser light is performed at a temperature that melts the semiconductor material near the lower surface of the semiconductor substrate SUB by laser annealing.

As a result, conductive impurities contained in the diffusion source are introduced from the diffusion source into the vicinity of the lower surface of the semiconductor substrate SUB and diffuse within the molten semiconductor material. That is, conductive impurities are supplemented from the diffusion source to the vicinity of the lower surface of the semiconductor substrate SUB, where the impurity concentration of the conductive impurities is lower than the peak value. Consequently, according to the basic concept, it is possible to suppress the decrease in the impurity concentration of conductive impurities near the lower surface of the semiconductor substrate SUB. Furthermore, within the molten semiconductor material, the conductive impurities diffuse almost uniformly. By supplementing conductive impurities from the diffusion source to the vicinity of the lower surface of the semiconductor substrate SUB and using laser annealing to diffuse the supplemented conductive impurities almost uniformly within the molten semiconductor material, the decrease in the impurity concentration of conductive impurities near the lower surface of the semiconductor substrate SUB is suppressed. Therefore, by adopting the basic concept, the contact between the lower surface of the semiconductor substrate and the lower electrode can be improved.

An embodiment that embodies the basic concept will be described below.

### First Embodiment

In the first embodiment, an example of applying the basic concept to a semiconductor device including an IGBT will be explained.

In the first embodiment, the “conductive impurity” of the basic concept is “boron”. “Boron” functions as a p-type impurity (acceptor). The “diffusion source” of the basic concept is a “film containing boron”. The “lower electrode” of the basic concept is a “collector electrode”.

In the first embodiment, the basic configuration of the semiconductor device including the IGBT has the same basic configuration as the semiconductor device 100 shown in FIG. 1. The semiconductor substrate SUB is a p-type semiconductor substrate. The semiconductor substrate SUB has an upper surface. The n-type epitaxial layer EPI is formed on the upper surface of the semiconductor substrate SUB. The n-type emitter region (emitter region ER1, emitter region ER2) is formed in the epitaxial layer EPI. The gate insulating film GOX is formed to partially in contact with the emitter region. The gate electrode GE is formed on the gate insulating film GOX. The semiconductor substrate SUB is a collector region.

The IGBT assumed in the first embodiment is a planar type IGBT as shown in FIG. 1. However, the technical concept of this disclosure is not limited to semiconductor devices including planar type IGBTs. The technical concept of this disclosure can also be applied to semiconductor devices including trench gate type IGBTs.

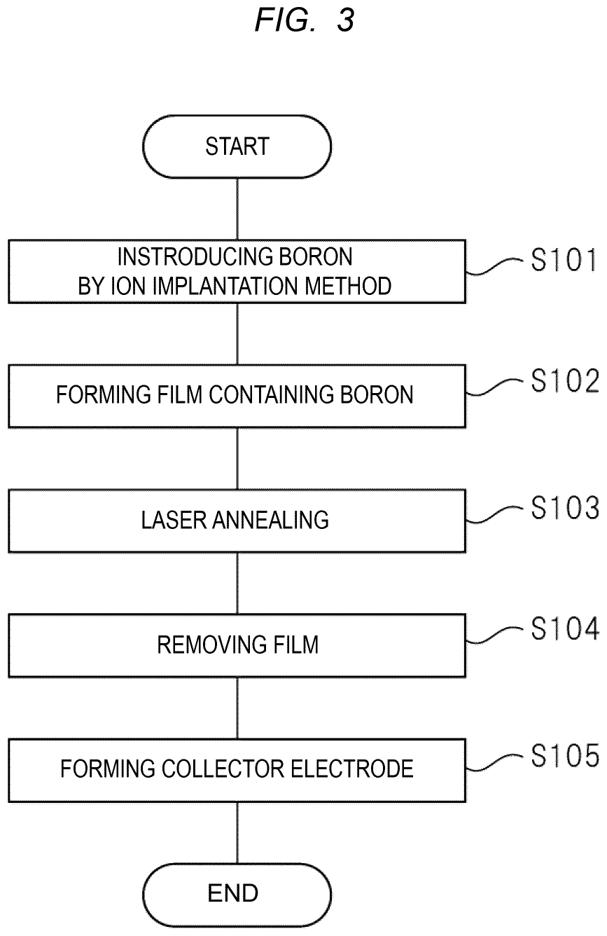

FIG. 3 is a flowchart explaining the first embodiment.

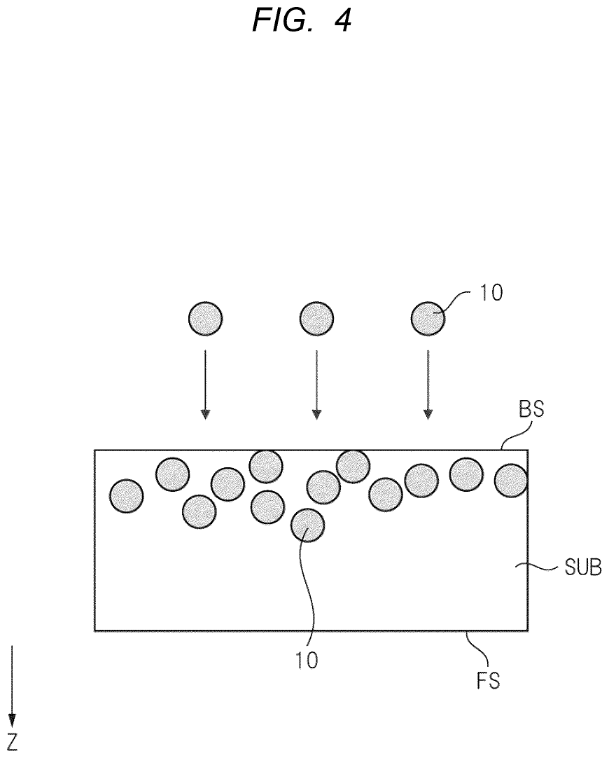

First, as shown in FIG. 4, the semiconductor substrate SUB has an upper surface FS and a lower surface BS. The semiconductor substrate SUB is made of, for example, semiconductor material, specifically silicon (Si). By using an ion implantation method, boron 10 (first conductive impurity) is introduced into the semiconductor substrate SUB from the lower surface BS (S101). In this state, the impurity concentration of boron introduced near the lower surface BS of the semiconductor substrate SUB is lower than the peak value. In other words, the peak value of the impurity concentration of boron introduced into the semiconductor substrate SUB is away from the lower surface BS of the semiconductor substrate SUB. Therefore, if a collector electrode is formed on the lower surface BS of the semiconductor substrate SUB immediately after this step, there is a risk that the ohmic contact between the lower surface BS and the collector electrode will be insufficient. Particularly, when manufacturing an IGBT with a low boron impurity concentration, the contact between the lower surface BS and the collector electrode tends to decrease.

Therefore, in the first embodiment, the following step is implemented.

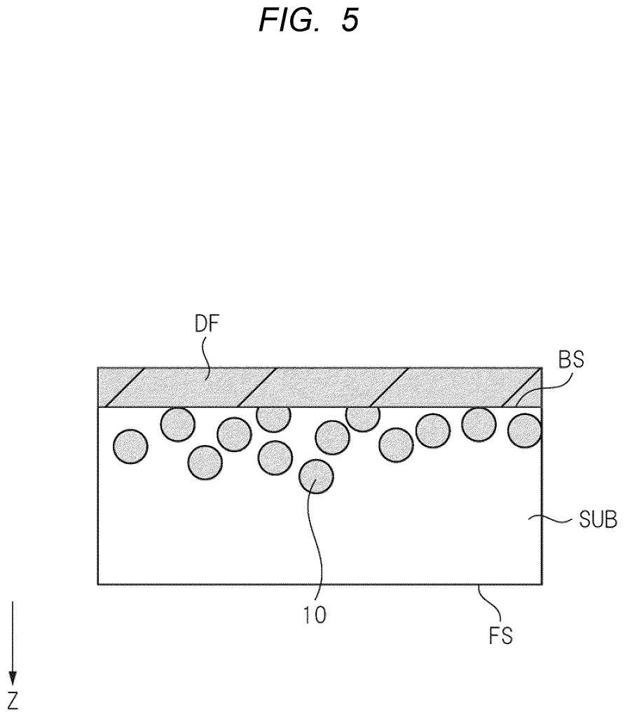

First, the semiconductor substrate SUB having a lower surface BS is prepared. Next, as shown in FIG. 5, a film DF is formed on the lower surface BS of the semiconductor substrate SUB (S102). The film DF contains boron (second conductive impurity). The film DF is, for example, a BPSG (Boro-Phospho Silicate Glass) film or a B₂O₃ film. A thickness of the film DF is about 1 nm or more and 100 nm or less.

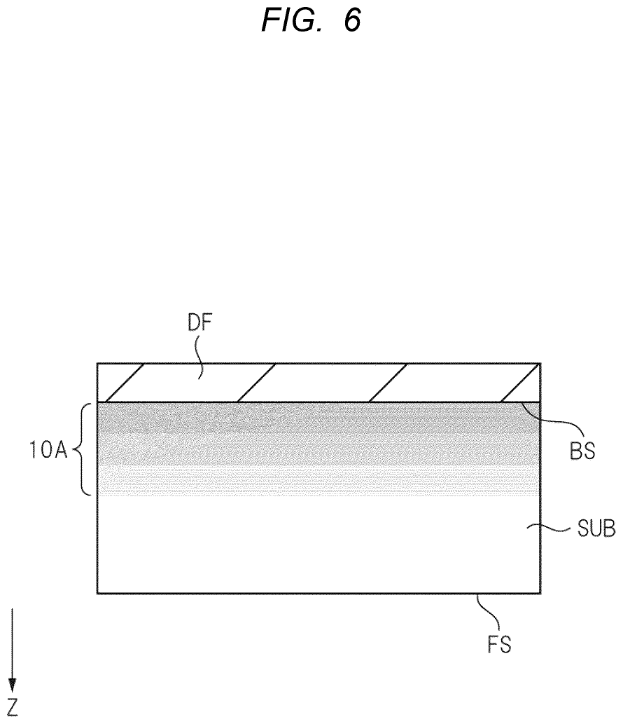

Next, as shown in FIG. 6, the laser light is irradiated onto the lower surface BS through the film DF (S103). The step of irradiating with laser light is carried out at a temperature that melts the silicon near the lower surface BS of the semiconductor substrate SUB by laser annealing. Specifically, in the laser light irradiation step, for example, the semiconductor material within the portion between 0 μm and 0.25 μm from the lower surface BS of the semiconductor substrate SUB in the direction perpendicular to the lower surface BS (Z direction) is melted.

For example, the irradiation energy of the laser light is about 1.8 J/cm². In this case, the temperature of the silicon within the portion of 0.25 μm or less in depth becomes instantaneously 1400 degrees Celsius or higher. As a result, silicon melts. Also, boron contained in the film DF is introduced into the semiconductor substrate SUB. Therefore, by the step of irradiating the lower surface of the semiconductor substrate SUB with laser light, boron is introduced into the semiconductor substrate SUB from the film DF (diffusion source). As a result, after the step of irradiating the lower surface of the semiconductor substrate SUB with laser light is implemented, boron introduced from the film DF is contained in the semiconductor substrate SUB.

Boron introduced from the film DF into the vicinity of the lower surface BS of the semiconductor substrate SUB diffuses within the molten silicon. Within the molten silicon, boron diffuses almost uniformly. This suppresses the decrease in the impurity concentration of boron near the lower surface BS of the semiconductor substrate SUB. FIG. 6 schematically shows that the impurity concentration distribution 10A of boron is almost uniform.

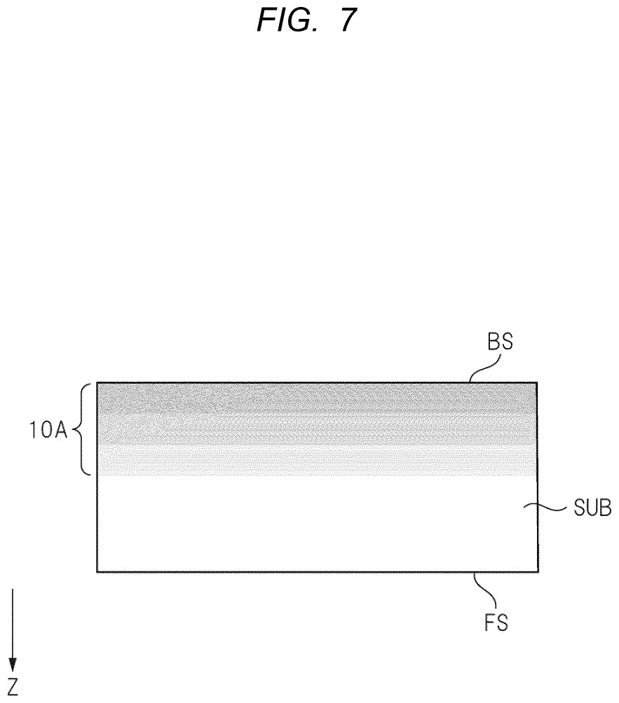

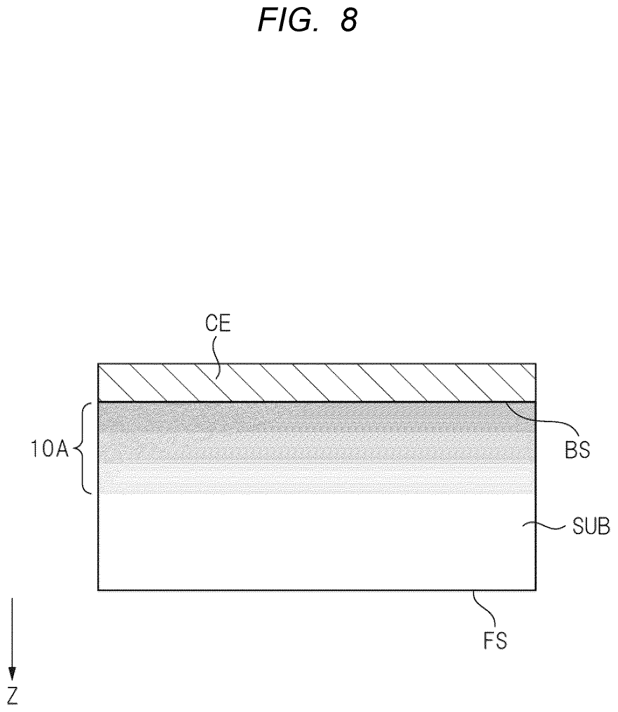

Subsequently, as shown in FIG. 7, the film DF is removed (S104). Then, as shown in FIG. 8, the collector electrode CE is formed on the lower surface BS of the semiconductor substrate SUB (S105). The collector electrode CE is a conductive film. The conductive film is, for example, an aluminum film (Al film), an aluminum silicide film (AlSi film), or a nickel silicide film (NiSi film). The conductive film can be formed, for example, by a sputtering method.

As described above, according to the first embodiment, it is possible to suppress the decrease in the impurity concentration of boron near the lower surface BS of the semiconductor substrate SUB. Therefore, according to the first embodiment, the contact between the lower surface BS of the semiconductor substrate SUB and the collector electrode CE can be improved. As a result, the on-voltage of the IGBT can be reduced. In other words, the on-resistance of the IGBT can be reduced.

The step described in the first embodiment includes the step of performing laser annealing to melt silicon in the state where the film DF containing boron is formed on the lower surface BS of the semiconductor substrate SUB. In this case, traces indicating that the step described in the first embodiment has been implemented remain on the lower surface BS of the semiconductor substrate SUB. This point will be explained below.

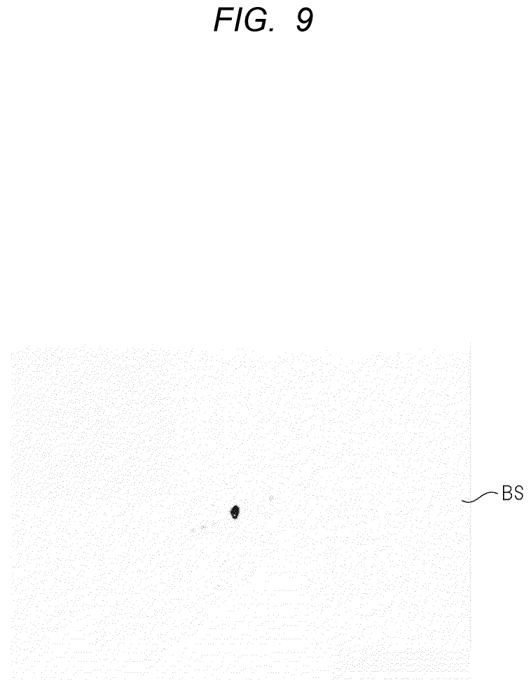

FIG. 9 is a diagram schematically showing the result of observing the lower surface BS of the semiconductor substrate SUB with a microscope in the case where laser annealing is performed without forming the film DF. As shown in FIG. 9, no wrinkle pattern is observed on the lower surface BS of the semiconductor substrate SUB.

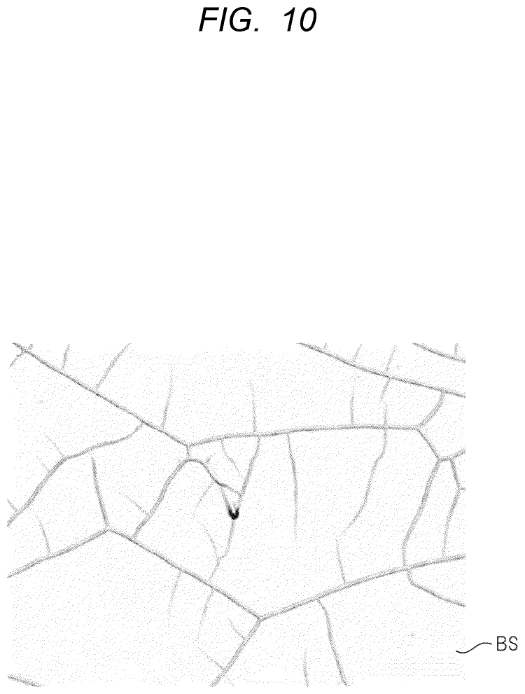

In contrast, FIG. 10 is a diagram schematically showing the result of observing the lower surface BS of the semiconductor substrate SUB with a microscope after performing laser annealing to melt silicon in the state where the film DF is formed and then removing the film DF. As shown in FIG. 10, a wrinkle pattern is observed on the lower surface BS of the semiconductor substrate SUB. This is understood as follows. That is, laser annealing is performed to melt silicon in the state where the film DF is formed. In this case, during the step of solidifying the molten silicon, uneven stress is applied from the film DF. As a result, due to the uneven stress, a relatively random wrinkle pattern is formed on the lower surface BS of the semiconductor substrate SUB.

Therefore, when the step described in the first embodiment is implemented, a wrinkle pattern is observed on the lower surface BS of the semiconductor substrate SUB. On the other hand, when laser annealing is performed without forming the film DF, no wrinkle pattern is observed. Therefore, by observing the presence or absence of a wrinkle pattern, it is possible to determine whether the step described in the first embodiment has been implemented or not.

### Second Embodiment

In the first embodiment, for example, as shown in FIG. 3, the step of introducing boron into the semiconductor substrate SUB by ion implantation method (S101) is implemented. In the first embodiment, subsequently, the step of forming the film DF containing boron on the lower surface BS of the semiconductor substrate SUB (S102) is implemented. In the second embodiment, before the step of introducing boron into the semiconductor substrate SUB by ion implantation method, the step of forming the film DF containing boron on the lower surface BS of the semiconductor substrate SUB is implemented.

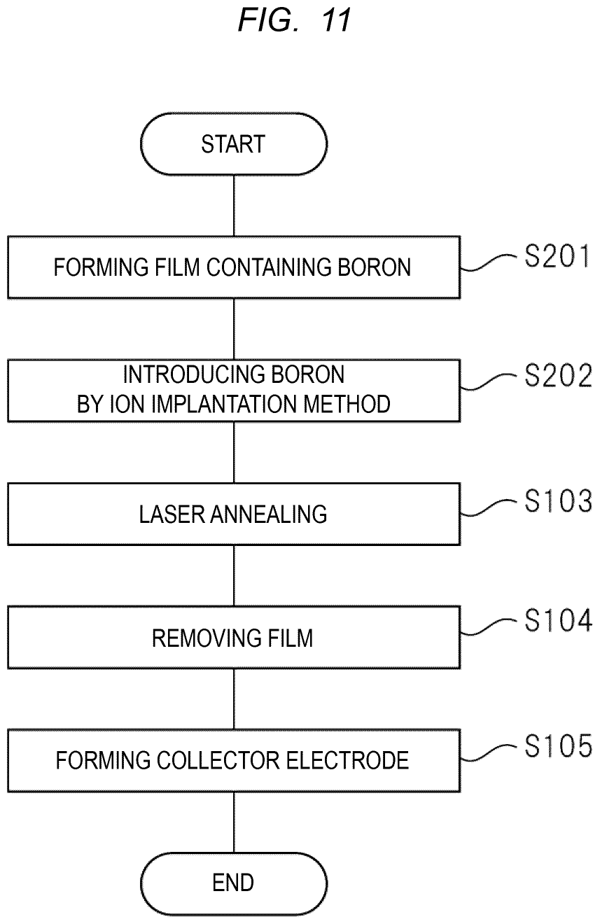

FIG. 11 is a flowchart explaining the second embodiment.

As shown in FIG. 11, in the second embodiment, first, a film containing boron is formed on the lower surface BS of the semiconductor substrate SUB (S201). Subsequently, the step of introducing boron into the semiconductor substrate SUB by ion implantation method is carried out (S202). The subsequent steps are the same as in the first embodiment.

In the second embodiment, the film DF containing boron is formed before the step of introducing boron into the semiconductor substrate SUB by ion implantation method. Therefore, the film DF containing boron also functions as a “through film” during the ion implantation step. In other words, in the second embodiment, the film DF containing boron is used not only as a diffusion source for boron but also as a “through film” during the ion implantation step. As a result, according to the second embodiment, the step of forming a “through film” can be omitted. Consequently, according to the second embodiment, the manufacturing cost of the semiconductor device can be reduced.

### Third Embodiment

In the third embodiment, the “conductive impurity” of the basic concept is “boron”. “Boron” functions as a p-type impurity (acceptor). The “diffusion source” of the basic concept is “boron attached to the lower surface of the semiconductor substrate”. The “lower electrode” of the basic concept is the “collector electrode”.

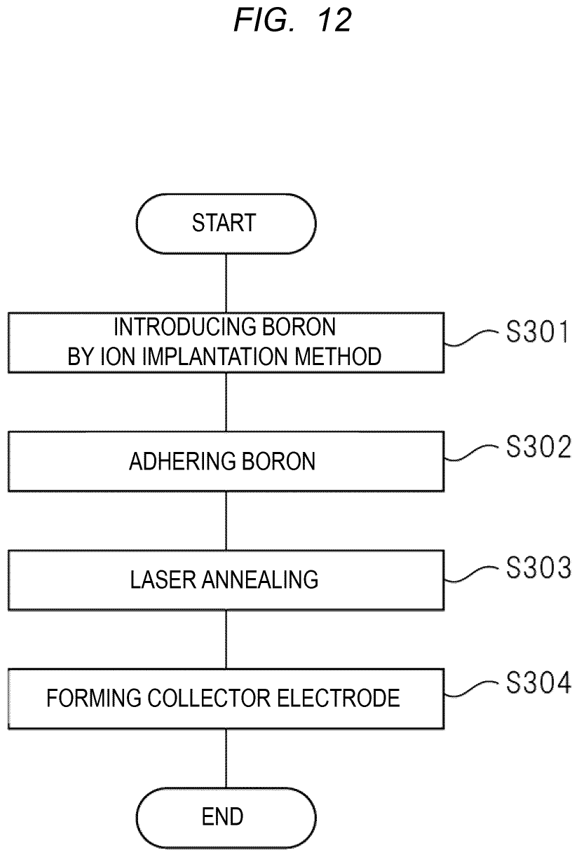

FIG. 12 is a flowchart explaining the third embodiment.

First, as shown in FIG. 4, the semiconductor substrate SUB has an upper surface FS and a lower surface BS. The semiconductor substrate SUB is made of, for example, a semiconductor material, specifically silicon (Si). By using ion implantation method, boron 10 is introduced into the semiconductor substrate SUB from the lower surface BS (S301). In this state, the impurity concentration of boron introduced near the lower surface BS of the semiconductor substrate SUB is lower than the peak value. Therefore, if a collector electrode is formed on the lower surface BS immediately after this step, there is a risk that the ohmic contact between the lower surface BS and the collector electrode will be insufficient. Particularly, when manufacturing an IGBT with a low boron impurity concentration, the contact between the lower surface BS and the collector electrode tends to decrease. Therefore, in the third embodiment, the following step is implemented.

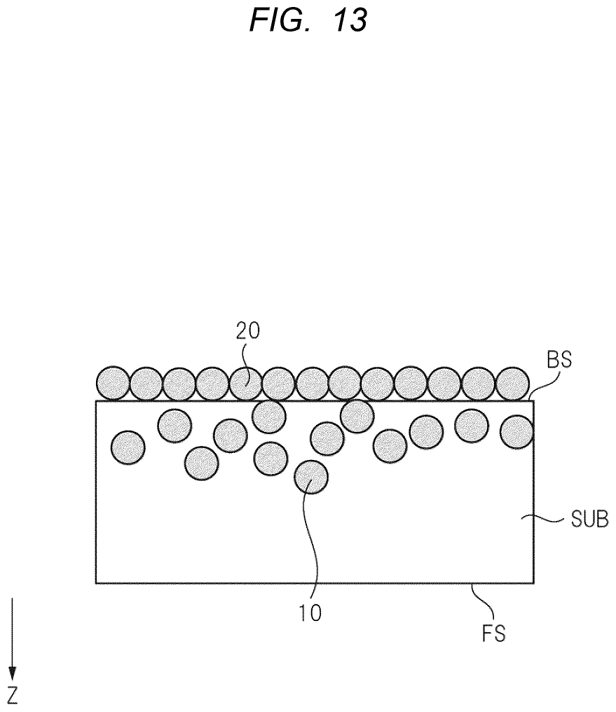

As shown in FIG. 13, boron 20 is deposited on the lower surface BS of the semiconductor substrate SUB (S302). Specifically, in the third embodiment, the semiconductor substrate SUB is transported with the lower surface BS of the semiconductor substrate SUB facing upward in a clean room equipped with an air filter containing boron 20. As a result, boron 20 scattered from the air filter adheres to the lower surface BS of the semiconductor substrate SUB.

To keep the air in the clean room clean, an air filter is provided in the air supply path to the clean room. The material of the air filter is glass fiber. However, from the perspective of cost reduction and ease of manufacturing the air filter, glass fiber material containing boron 20 may be used as the material of the air filter. Therefore, the air in the clean room equipped with an air filter containing boron 20 contains boron 20. In the third embodiment, boron 20 contained in the air in the clean room is used as a diffusion source.

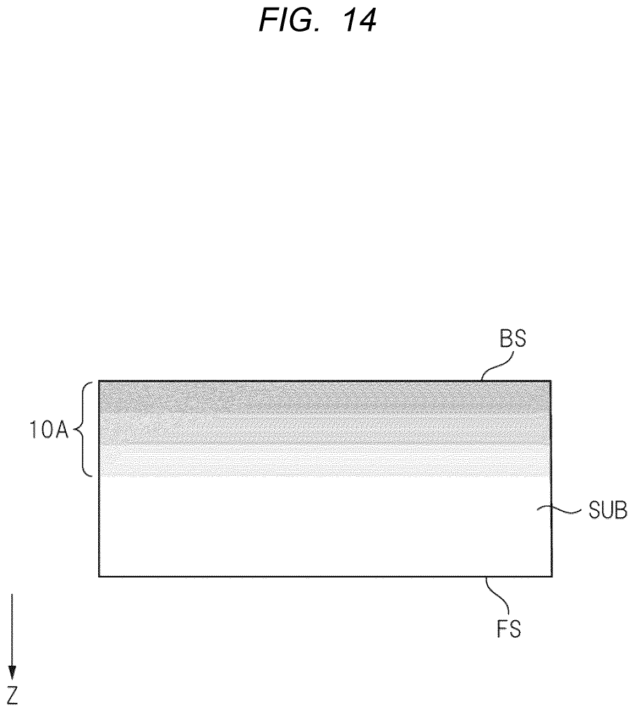

Next, as shown in FIG. 14, laser light is irradiated onto the lower surface BS to which boron 20 has been attached (S303). The step of irradiating laser light is carried out at a temperature that melts the silicon near the lower surface BS of the semiconductor substrate SUB by laser annealing. Specifically, in the laser light irradiation step, for example, the semiconductor material within the portion between 0 μm and 0.25 μm from the lower surface BS of the semiconductor substrate SUB in the direction perpendicular to the lower surface BS (Z direction) is melted.

For example, the irradiation energy of the laser light is about 1.8 J/cm². In this case, the temperature of the silicon within the portion of 0.25 μm or less in depth momentarily exceeds 1400 degrees Celsius. As a result, silicon melts. Additionally, boron 20 adhering to the lower surface BS is introduced into the semiconductor substrate SUB.

Boron 20 introduced near the lower surface BS of the semiconductor substrate SUB diffuses within the melted silicon. In the melted silicon, boron 20 diffuses almost uniformly. This suppresses the decrease in the impurity concentration of boron 10 near the lower surface BS of the semiconductor substrate SUB. FIG. 14 schematically shows that the total impurity concentration distribution 10A of boron 10 and boron 20 is almost uniform.

Subsequently, as shown in FIG. 8, the collector electrode CE is formed on the lower surface BS of the semiconductor substrate SUB (S304). The collector electrode CE is a conductive film. The conductive film is, for example, an aluminum film (Al film), an aluminum silicide film (AlSi film), or a nickel silicide film (NiSi film). The conductive film can be formed by, for example, a sputtering method.

As described above, according to the third embodiment, the decrease in the impurity concentration of boron 10 near the lower surface BS of the semiconductor substrate SUB can be suppressed. Therefore, according to the third embodiment, the contact between the lower surface BS of the semiconductor substrate SUB and the collector electrode CE can be improved. As a result, the on-voltage of the IGBT can be reduced. In other words, the on-resistance of the IGBT can be reduced.

### Fourth Embodiment

In the fourth embodiment, an example is described in which the step of depositing boron on the lower surface is carried out without implementing the ion implantation step of introducing boron into the semiconductor substrate from the lower surface by ion implantation method. In other words, the fourth embodiment is one embodiment for minimizing the impurity concentration of boron in the semiconductor substrate. In the fourth embodiment, S101 is not implemented in FIG. 12, and S102 to S104 are implemented.

The present inventors have analyzed the impurity concentration of boron using SIMS (Secondary Ion Mass Spectrometry) for examples and comparative examples. In the example, laser annealing is performed after depositing boron on the lower surface of the semiconductor substrate. In the comparative example, laser annealing is performed without depositing boron on the lower surface of the semiconductor substrate.

As a result of the analysis, in the comparative example, the impurity concentration of boron in the range from a depth of 0 μm (lower surface) to a depth of 0.3 μm is about 1×10¹⁵ (/cm³) to 1×10¹⁶ (/cm³). In contrast, in the example, the impurity concentration of boron in the range from a depth of 0 μm (lower surface) to a depth of 0.3 μm is about 2×10¹⁶ (/cm³) to 1×10¹⁷ (/cm³).

From this result, the boron introduced into the semiconductor substrate by the fourth embodiment has the minimum necessary impurity concentration corresponding to the design specifications for high-speed switching applications of IGBT.

Also, in the fourth embodiment, the decrease in the impurity concentration of boron near the lower surface BS of the semiconductor substrate SUB can be suppressed. Therefore, according to the fourth embodiment, the contact between the lower surface BS of the semiconductor substrate SUB and the collector electrode CE can be improved. As a result, the on-voltage of the IGBT can be reduced. In other words, the on-resistance of the IGBT can be reduced.

Therefore, in the fourth embodiment, in the IGBT for high-speed switching applications, the contact between the lower surface of the semiconductor substrate and the collector electrode can be improved while meeting the design specifications regarding the impurity concentration of boron.

### Fifth Embodiment

In the fifth embodiment, an example is described in which the basic concept is applied to a semiconductor device including a diode.

The “conductive impurity” of the basic concept is “phosphorus”. “Phosphorus” functions as an n-type impurity (donor). The “diffusion source” of the basic concept is a “film containing phosphorus” or “phosphorus attached to the lower surface of the semiconductor substrate”. The “lower electrode” of the basic concept is the “cathode electrode”.

An inverter, which is a power conversion device, is used, for example, to drive a motor. The inverter has an upper arm and a lower arm. Specifically, the upper arm and the lower arm are connected in a series between the power supply wiring and the ground wiring. The upper arm and the lower arm have similar configurations. Therefore, hereinafter, the upper arm and the lower arm are simply referred to as “arm” without distinction.

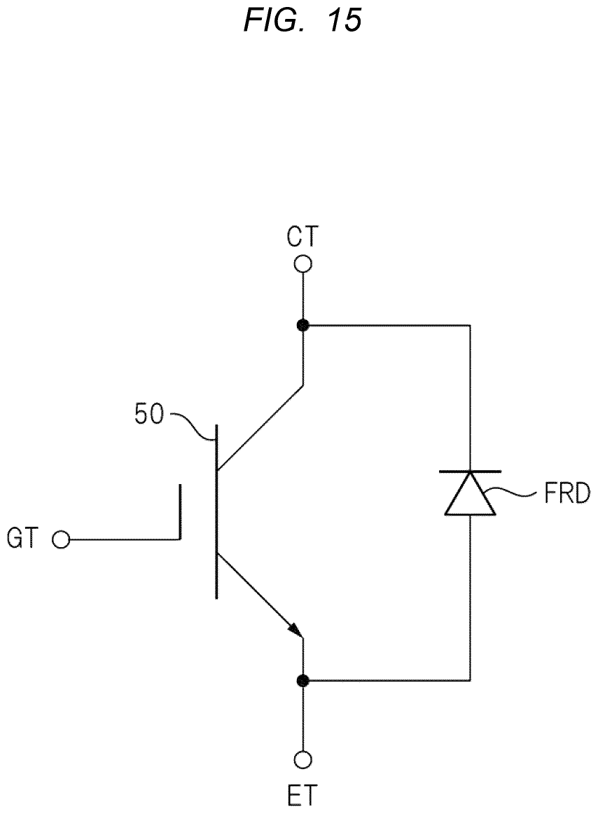

FIG. 15 is a circuit diagram configuring the arm.

As shown in FIG. 15, the arm includes an IGBT 50 and a diode FRD. The IGBT 50 is a switching element. The IGBT 50 has a gate terminal GT, a collector terminal CT, and an emitter terminal ET.

In the IGBT 50, in a state where a positive potential is applied to the collector terminal CT while the emitter terminal ET is grounded, a gate voltage equal to or greater than the threshold voltage is applied to the gate terminal GT. As a result, the IGBT 50 turns on, allowing current to flow from the collector terminal CT to the emitter terminal ET. In this state, if a gate voltage lower than the threshold voltage is applied to the gate terminal GT, the IGBT 50 turns off, and the current is interrupted. By alternately repeating the on and off operations of the IGBT 50 as described above, the motor is driven.

The motor includes inductance. Therefore, due to the inductance, back electromotive force may be generated. When back electromotive force is generated, a positive potential is applied to the emitter terminal ET shown in FIG. 15, while a potential lower than that applied to the emitter terminal ET is applied to the collector terminal CT. That is, the potential of the emitter terminal ET becomes higher than the potential of the collector terminal CT. In this case, reverse current tends to flow from the emitter terminal ET to the collector terminal CT. However, the IGBT 50 does not have the function to allow reverse current to flow from the emitter terminal ET to the collector terminal CT.

Therefore, to allow reverse current due to inductance to flow, as shown in FIG. 15, a diode FRD is provided in reverse parallel connection with the IGBT 50. As a result, the reverse current flows from the emitter terminal ET to the collector terminal CT via the diode FRD.

The diode FRD is called a “freewheeling diode”. The diode FRD is, for example, a Schottky barrier diode or a pn junction diode. The case where the diode FRD is a pn junction diode will be described below.

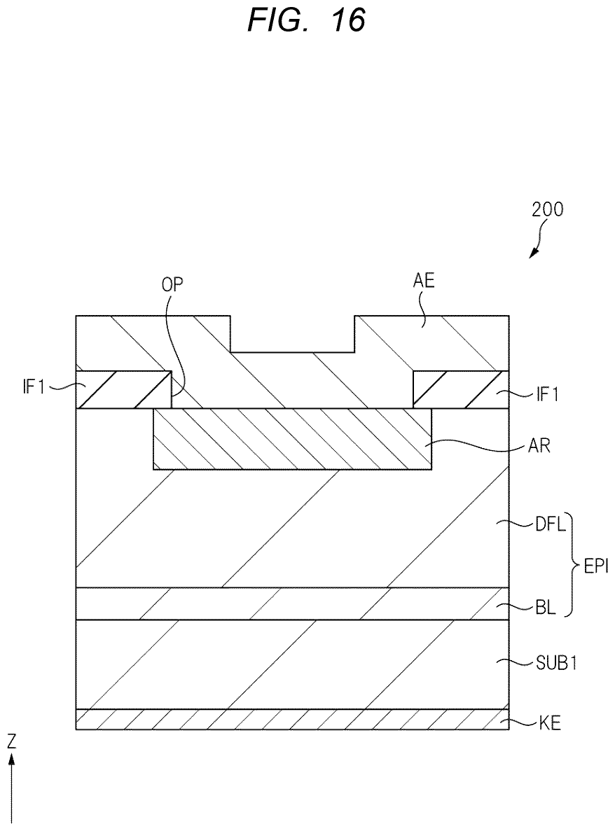

FIG. 16 is a cross-sectional view showing the configuration of a semiconductor device 200 including a diode.

The semiconductor device 200 includes a semiconductor substrate SUB1, a buffer layer BL, a drift layer DFL, an anode region AR, an interlayer insulating film IF1, a cathode electrode KE, and an anode electrode AE.

The semiconductor substrate SUB1 is an n-type silicon substrate. That is, for example, phosphorus, which is an n-type impurity, is introduced into the semiconductor substrate SUB1. An epitaxial layer EPI is formed on the upper surface of the semiconductor substrate SUB1. The epitaxial layer EPI includes the buffer layer BL and the drift layer DFL. A cathode electrode KE is formed on the lower surface of the semiconductor substrate SUB1. The cathode electrode KE is the lower electrode.

In the epitaxial layer EPI, the anode region AR of the diode is formed. The anode region AR is a p-type semiconductor region. For example, boron, which is a p-type impurity, is introduced into the anode region AR. The epitaxial layer EPI is an n-type semiconductor layer. On the other hand, the anode region AR is a p-type semiconductor region. Therefore, a pn junction is formed at the interface between the epitaxial layer EPI and the anode region AR. The semiconductor substrate SUB1 and the epitaxial layer EPI are the cathode region of the diode.

The interlayer insulating film IL1 is formed on the epitaxial layer EPI having the anode region AR. An opening OP is formed in the interlayer insulating film IL1. A part of the upper surface of the anode region AR is exposed from the opening OP. An anode electrode AE is formed on the interlayer insulating film IL1, including the inside of the opening OP. An ohmic contact is formed between the anode electrode AE and the anode region AR.

In the semiconductor device 200 including a diode, it is important to reduce the on-voltage. Therefore, it is necessary to secure sufficient contact between the lower surface of the semiconductor substrate SUB1 and the cathode electrode KE. For example, the following step is implemented to secure sufficient contact between the lower surface of the semiconductor substrate SUB1 and the cathode electrode KE.

Specifically, phosphorus is introduced into the semiconductor substrate SUB1 from the lower surface of the semiconductor substrate SUB1 by ion implantation method. Subsequently, laser annealing is performed by irradiating the lower surface with laser light. This activates the phosphorus introduced into the semiconductor substrate SUB1. After that, the cathode electrode KE made of a conductive film is formed on the lower surface of the semiconductor substrate SUB1. This forms an ohmic contact between the lower surface of the semiconductor substrate SUB1 and the cathode electrode KE. As a result, sufficient contact between the lower surface of the semiconductor substrate SUB1 and the cathode electrode KE can be secured.

The impurity concentration of phosphorus introduced near the lower surface is lower than the peak value, meaning the peak value of the impurity concentration of phosphorus introduced near the lower surface is away from the lower surface. Therefore, there is a risk that the contact between the lower surface and the cathode electrode KE may decrease. Thus, the technical concepts described in the first embodiment 1 to the fourth embodiment 4 can also be applied to the fifth embodiment. In other words, the technical concepts from the first embodiment 1 to the fourth embodiment with regard to the semiconductor device 100 including an IGBT are also effective when applied to the semiconductor device 200 including a diode.

In this case, by the step of irradiating the lower surface of the semiconductor substrate SUB1 with laser light, phosphorus is introduced into the semiconductor substrate SUB1 from a diffusion source. As a result, after the step of irradiating the lower surface of the semiconductor substrate SUB1 with laser light, phosphorus introduced from the diffusion source is contained in the semiconductor substrate SUB1.

### Sixth Embodiment

The sixth embodiment is an application example of the basic concept for a semiconductor device including a diode.

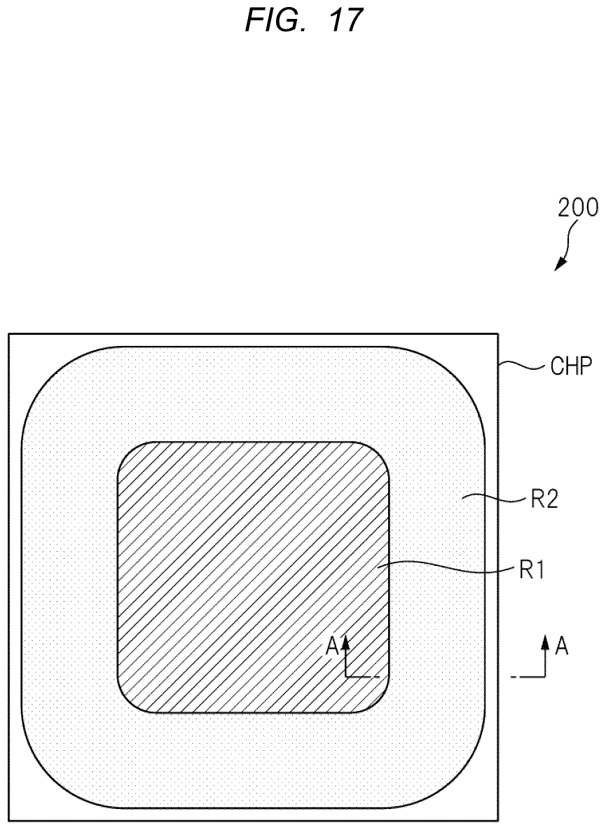

FIG. 17 is a plan view showing the configuration of a semiconductor device 200 including a diode.

In FIG. 17, the semiconductor device 200 includes a semiconductor chip CHP. The planar shape of the semiconductor chip CHP is, for example, rectangular. The semiconductor chip CHP includes a cell portion R1 having a diode and a peripheral portion R2 surrounding the cell portion R1 in a planar manner.

The sixth embodiment will be described below in comparison with an examined example.

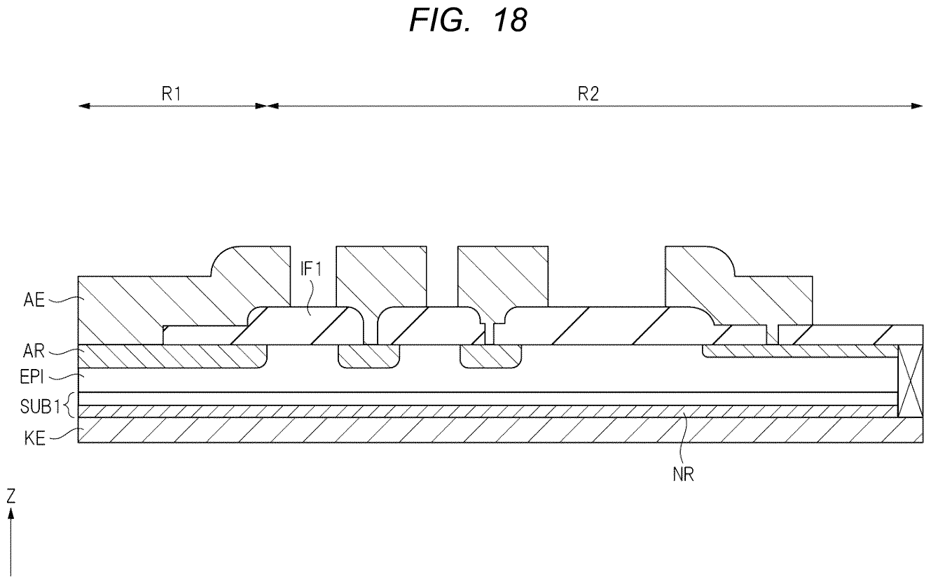

FIG. 18 is a diagram showing the examined example. In the examined example, an n-type semiconductor region NR is formed at the lower surface of the semiconductor substrate SUB1. This n-type semiconductor region NR is formed using the technical concept of the present disclosure. Specifically, after forming a diffusion source of n-type impurities on the lower surface of the semiconductor substrate SUB1, laser light is irradiated through the diffusion source into the lower surface of the semiconductor substrate SUB1. This diffuses n-type impurities into the semiconductor substrate SUB1 while melting silicon near the lower surface. As a result, the n-type semiconductor region NR with a nearly uniform impurity concentration is formed.

In the examined example, the n-type semiconductor region NR is formed not only in the cell portion R1 but also in the peripheral portion R2. In this case, the inventor has newly discovered the following insights.

Specifically, in the examined example, the n-type semiconductor region NR is also formed in the peripheral portion R2. Therefore, when a forward bias is applied to the diode, electrons are injected into the epitaxial layer EPI not only from the n-type semiconductor region NR of the cell portion R1 but also from the n-type semiconductor region NR of the peripheral portion R2. Meanwhile, holes are injected into the epitaxial layer EPI from the anode region AR, which is a p-type semiconductor region. Here, in the examined example, since electrons are also injected into the epitaxial layer EPI from the peripheral portion R2, the amount of electron injection increases. Therefore, the amount of hole injection from the anode region AR into the epitaxial layer EPI also increases.

In this state, when a reverse bias is applied to the diode, electrons and holes injected into the epitaxial layer EPI are discharged (recovery operation). At this time, in the examined example, the amount of injected electrons and holes is large. Focusing on the discharge of holes, the holes are discharged from the anode electrode AE through the anode region AR. However, the anode electrode AE is only formed in the cell portion R1. Therefore, a large number of holes discharged from the epitaxial layer EPI concentrate at the end of the anode electrode AE. As a result, there is a risk of the anode electrode AE being damaged. Therefore, in the sixth embodiment, the following configuration is adopted.

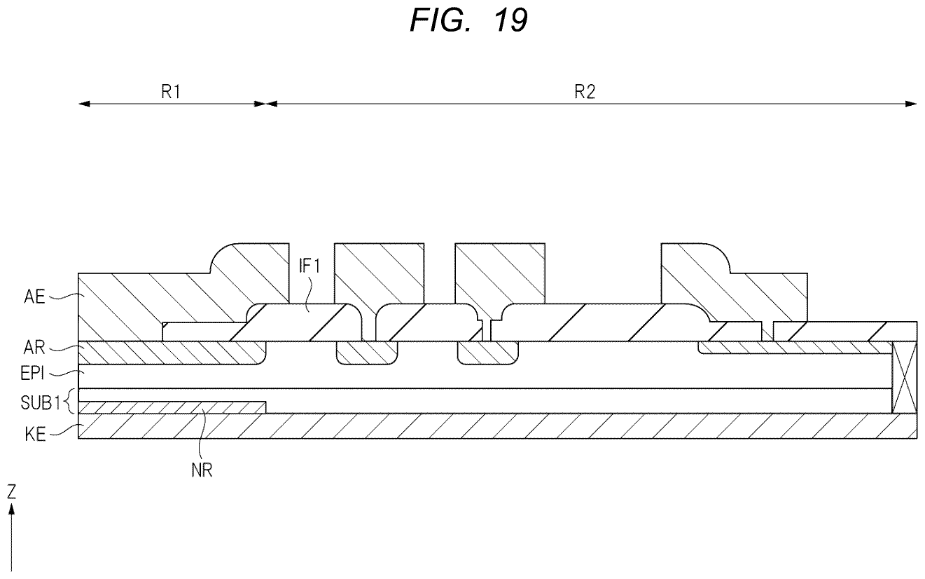

FIG. 19 is a cross-sectional view of a semiconductor device along line A-A of FIG. 17, showing the sixth embodiment. In FIG. 19, a feature of sixth embodiment is that the n-type semiconductor region NR is only formed in the cell portion R1. In other words, unlike the examined example, the n-type semiconductor region NR is not formed in the peripheral portion R2. In this case, when a forward bias is applied to the diode, it becomes difficult for electrons to be injected into the epitaxial layer EPI from the peripheral portion R2. Therefore, the amount of electrons injected into the epitaxial layer EPI is less compared to the examined example. As a result, the amount of holes injected from the anode region AR into the epitaxial layer EPI is also less than in the examined example. Thus, in the sixth embodiment, when a reverse bias is applied to the diode and recovery operation is performed, it is possible to suppress the concentration of holes at the end of the anode electrode AE compared to the examined example. That is, according to the sixth embodiment, it is possible to suppress the destruction of the anode electrode AE.

For example, to form the n-type semiconductor region NR in the cell portion R1 while not forming the n-type semiconductor region NR in the peripheral portion R2 using an ion implantation method, the following steps are necessary. Specifically, it is necessary to perform ion implantation method through a patterned mask using photolithography technique. In this case, since the number of steps increases, the manufacturing cost of the semiconductor device including the diode increases.

In contrast, the sixth embodiment applies the basic idea. That is, in the sixth embodiment, the n-type semiconductor region NR is formed by irradiating laser light through laser annealing. In this case, the irradiation position of the laser light can be set. Therefore, it is possible to set the irradiation position of the laser light so that laser light is irradiated onto the cell portion R1 while laser light is not irradiated onto the peripheral portion R2. That is, the lower surface of the semiconductor substrate SUB1 has the lower surface of the cell portion R1 and the lower surface of the peripheral portion R2. In the step of irradiating laser light, laser light is irradiated onto the lower surface of the cell portion R1 while laser light is not irradiated onto the lower surface of the peripheral portion R2. This allows the n-type semiconductor region NR to be formed only in the cell portion R1.

According to the sixth embodiment, photolithography technique is not used. That is, in the sixth embodiment, the number of steps does not increase as in the examined example. Therefore, according to the sixth embodiment, it is possible to suppress the increase in manufacturing cost of semiconductor devices including diode.

### Seventh Embodiment

The seventh embodiment is an application example of the basic idea for a semiconductor device including a diode.

In the semiconductor device 200 shown in FIG. 16, during recovery operation, electrons may be rapidly discharged from the epitaxial layer EPI to the cathode electrode KE via the semiconductor substrate SUB1. Particularly, when the thickness of the semiconductor substrate SUB1 and the epitaxial layer EPI is reduced to improve the characteristics of the diode, the rapid discharge of electrons becomes apparent. The rapid discharge of electrons leads to a rapid change in recovery current.

The diode included in the semiconductor device 200 is used, for example, as a “freewheeling diode”, which is a component of an inverter. An inverter is a circuit that drives a motor, for example. The motor includes inductance. Therefore, when the rapid change in recovery current described above flows into the motor, a large back electromotive force is generated. As a result, “ringing” occurs in the waveform of the recovery current.

Therefore, a semiconductor device including a diode that can suppress “ringing” is being considered.

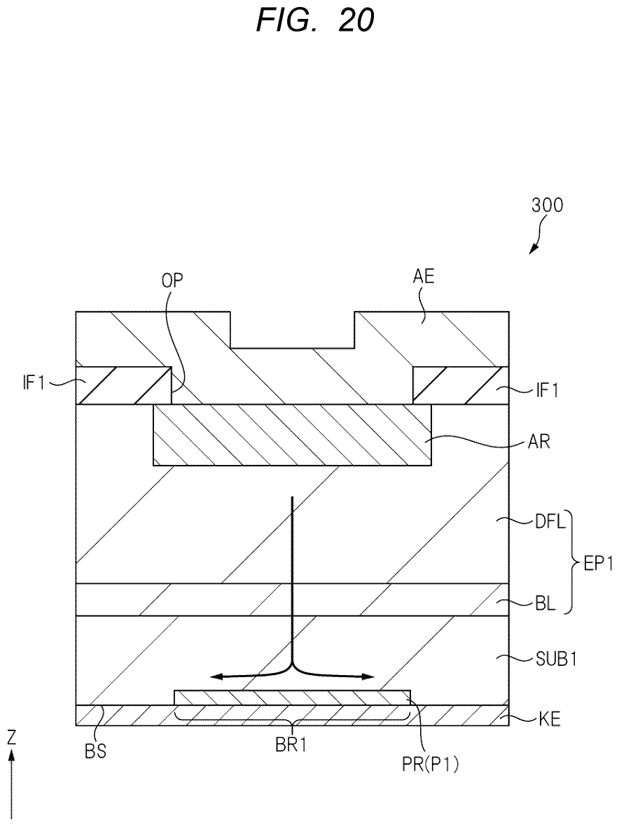

FIG. 20 is a cross-sectional view showing the configuration of a semiconductor device 300 including a diode.

In FIG. 20, the semiconductor substrate SUB1 is an n-type semiconductor substrate. In the first portion P1 of the semiconductor substrate SUB1, for example, a p-type semiconductor region PR into which boron is introduced is formed. Electrons discharged during recovery operation move along a path from the epitaxial layer EPI to the cathode electrode KE via the semiconductor substrate SUB1.

However, in the semiconductor device 300, the p-type semiconductor region PR is formed. Electrons cannot pass through the interior of the p-type semiconductor region PR. Therefore, during recovery operation, electrons discharged from the epitaxial layer EPI detour through the path indicated by the arrow in FIG. 20. As a result, it takes time to discharge the electrons. This means that the change in recovery current is mitigated. Consequently, since the abrupt change in recovery current is suppressed, the back electromotive force generated when the recovery current flows through the motor can be reduced. Therefore, according to the semiconductor device 300, “ringing” can be suppressed. Thus, from the perspective of suppressing “ringing”, it is useful to form the p-type semiconductor region PR in the semiconductor substrate SUB1.

For example, the p-type semiconductor region PR can be formed by using an ion implantation method. In this case, it is necessary to perform the ion implantation method through a patterned mask using photolithography technique. However, this method increases the number of steps, thereby increasing the manufacturing cost of the semiconductor device 300 including a diode.

In contrast, the seventh embodiment applies the basic concept. That is, in the seventh embodiment, boron (a third conductive impurity) of a p-type (second conductivity type) different from the n-type (first conductivity type) is introduced into the first portion P1 of the semiconductor substrate SUB1. Subsequently, the p-type semiconductor region PR is formed by irradiating laser light through laser annealing. In this case, the irradiation position of the laser light can be set. Therefore, in the seventh embodiment, by implementing the following steps, the p-type semiconductor region PR can be formed in the first portion P1 of the semiconductor substrate SUB1.

Specifically, in the seventh embodiment, a step is implemented to form, a diffusion source for diffusing boron into the first portion P1 of the semiconductor substrate SUB1, on the lower surface BS of the semiconductor substrate SUB1. Subsequently, a step is implemented to irradiate laser light onto the lower surface BS of the semiconductor substrate SUB1 through the diffusion source. In the step of irradiating laser light, laser light is irradiated onto the first region BR1 of the lower surface BS included in the first portion P1, while laser light is not irradiated onto a region other than the first region BR1 of the lower surface BS. As a result, boron is supplemented from the diffusion source to the vicinity of the first region BR1 of the lower surface BS of the semiconductor substrate SUB1, where the impurity concentration of boron is lower than the peak value. Then, through laser annealing, the supplemented boron can be diffused almost uniformly within the molten silicon. Therefore, according to the seventh embodiment, the p-type semiconductor region PR can be formed in the vicinity of the first region BR1 of the lower surface BS, where the decrease in boron impurity concentration is suppressed.

According to the seventh embodiment, photolithography technique is not used. Therefore, according to the seventh embodiment, the increase in manufacturing cost of the semiconductor device 300 including a diode, can be suppressed.

The invention made by the present inventor has been described above in detail based on the embodiment, but the present invention is not limited to the embodiment described above, and needless to say that various modifications can be made without departing from the gist thereof.

What is claimed is:

1. A method of manufacturing a semiconductor device, the method comprising:
(a) preparing a semiconductor substrate having a lower surface;
(b) introducing a first conductive impurity of a first conductivity type into the semiconductor substrate from the lower surface of the semiconductor substrate using ion implantation method;
(c) forming a film containing a second conductive impurity of the first conductivity type on the lower surface;
(d) after the (c), irradiating the lower surface with laser light through the film;
(e) after the (d), removing the film; and
(f) after the (e), forming a conductive film on the lower surface.

2. The method according to claim 1,
wherein the (c) is performed after the (b).

3. The method according to claim 1,
wherein the (c) is performed before the (b).

4. The method according to claim 1,
wherein the semiconductor substrate is formed of a semiconductor material, and
wherein in the (d), the semiconductor material within a portion between 0 μm and 0.25 μm from the lower surface of the semiconductor substrate in a direction perpendicular to the lower surface is melted.

5. The method according to claim 1,
wherein the semiconductor substrate comprises:
a cell portion having a pn junction diode; and
a peripheral portion surrounding the cell portion in a planar manner,
wherein the lower surface of the semiconductor substrate comprises a lower surface of the cell portion and a lower surface of the peripheral portion, and
wherein in the (d), the laser light is irradiated onto the lower surface of the cell portion while the laser light is not irradiated onto the lower surface of the peripheral portion.

6. The method according to claim 1,
wherein the semiconductor substrate is of the first conductivity type,
wherein in the (b), a third conductive impurity of a second conductivity type different from the first conductivity type is introduced into a first portion of the semiconductor substrate, and
wherein in the (d), the laser light is irradiated onto a first region of the lower surface included in the first portion, while the laser light is not irradiated onto a region other than the first region of the lower surface.

7. The method according to claim 1,
wherein the semiconductor substrate is of the first conductivity type,
wherein the semiconductor substrate has an upper surface,
wherein an epitaxial layer of the first conductivity type is formed on the upper surface of the semiconductor substrate,
wherein an anode region of a second conductivity type different from the first conductivity type, which configures a diode, is formed in the epitaxial layer,
wherein the semiconductor substrate and the epitaxial layer are a cathode region of the diode, and
wherein after the (d), the semiconductor substrate contains the second conductive impurity.

8. The method according to claim 7,
wherein the first conductive impurity is an n-type impurity, and
wherein the second conductive impurity is an n-type impurity.

9. The method according to claim 8,
wherein the first conductive impurity is phosphorus, and
wherein the second conductive impurity is phosphorus.

10. The method according to claim 1,
wherein the semiconductor substrate is of the first conductivity type,
wherein the semiconductor substrate has an upper surface,
wherein an epitaxial layer of a second conductivity type different from the first conductivity type is formed on the upper surface of the semiconductor substrate,
wherein an emitter region of the second conductivity type, which configures an IGBT, is formed in the epitaxial layer,
wherein a gate electrode of the IGBT is formed on a gate insulating film partially in contact with the emitter region,
wherein the semiconductor substrate is a collector region of the IGBT, and
wherein after the (d), the semiconductor substrate contains the second conductive impurity.

11. The method according to claim 10,
wherein the first conductive impurity is a p-type impurity, and
wherein the second conductive impurity is a p-type impurity.

12. The method according to claim 11,
wherein the first conductive impurity is boron, and
wherein the second conductive impurity is boron.

13. A method of manufacturing a semiconductor device, the method comprising:
(a) preparing a semiconductor substrate having a lower surface;
(b) depositing a first conductive impurity of a first conductivity type on the lower surface;
(c) after the (b), irradiating the lower surface with laser light; and
(d) after the (c), forming a conductive film on the lower surface.

14. The method according to claim 13,
wherein the first conductive impurity is boron, and
wherein in the (b), the semiconductor substrate is transported with the lower surface of the semiconductor substrate facing upward in a clean room equipped with an air filter containing boron.

15. The method according to claim 13,
wherein the semiconductor substrate is formed of a semiconductor material, and
wherein in the (c), the semiconductor material within a portion between 0 μm and 0.25 μm from the lower surface of the semiconductor substrate in a direction perpendicular to the lower surface is melted.

16. The method according to claim 13,
wherein the semiconductor substrate comprises:
a cell portion having a pn junction diode; and
a peripheral portion surrounding the cell portion in a planar manner,
wherein the lower surface of the semiconductor substrate comprises a lower surface of the cell portion and a lower surface of the peripheral portion, and
wherein in the (c), the laser light is irradiated onto the lower surface of the cell portion while the laser light is not irradiated onto the lower surface of the peripheral portion.

17. The method according to claim 13,
wherein the semiconductor substrate is of a second conductivity type different from the first conductivity type, and
wherein in the (c), the laser light is irradiated onto a first region of the lower surface while the laser light is not irradiated onto a region other than the first region of the lower surface.

18. The method according to claim 13,
wherein the semiconductor substrate is of the first conductivity type,
wherein the semiconductor substrate has an upper surface,
wherein an epitaxial layer of the first conductivity type is formed on the upper surface of the semiconductor substrate,
wherein an anode region of a second conductivity type different from the first conductivity type, which configures a diode, is formed in the epitaxial layer,
wherein the semiconductor substrate and the epitaxial layer are a cathode region of the diode,
wherein the first conductive impurity is phosphorus, and
wherein after the (c), the semiconductor substrate contains the first conductive impurity.

19. The method according to claim 13,
wherein the semiconductor substrate is of the first conductivity type,
wherein the semiconductor substrate has an upper surface,
wherein an epitaxial layer of a second conductivity type different from the first conductivity type is formed on the upper surface of the semiconductor substrate,
wherein an emitter region of the second conductivity type, which configures an IGBT, is formed in the epitaxial layer,
wherein a gate electrode of the IGBT is formed on a gate insulating film partially in contact with the emitter region,
wherein the semiconductor substrate is a collector region of the IGBT,
wherein the first conductive impurity is boron, and
wherein after the (c), the semiconductor substrate contains the first conductive impurity.
